(19) United States
(12) Patent Application Publication
(10) Pub. No.: US 2012/0105755 A1
(43) Pub. Date: May 3, 2012

(54) ACTIVE DEVICE ARRAY SUBSTRATE AND LIQUID CRYSTAL DISPLAY PANEL

(75) Inventors: Tsu-Te Zen, Kaohsiung County (TW); Han-Tung Hsu, Taoyuan County (TW)

(73) Assignee: CHUNGHWA PICTURE TUBES, LTD., Taoyuan (TW)

(21) Appl. No.: 12/960,549

(22) Filed: Dec. 6, 2010

(30) Foreign Application Priority Data
Oct. 27, 2010 (TW) 99220793

(51) Int. Cl. G02F 1/136; H01L 33/08

(52) U.S. Cl. 349/42; 257/91; 257/E33.066

(57) ABSTRACT

An active device array substrate includes a substrate, a pixel array, a peripheral circuit and at least an auxiliary metal pattern. The substrate has an active area and a peripheral circuit area connected to the active area. The pixel array is disposed on the active area of the substrate. The peripheral circuit is disposed on the peripheral circuit area of the substrate. The peripheral circuit includes a plurality of driver bonding pads and a plurality of fan-out line units. Each fan-out line unit includes a plurality of fan-out lines, a plurality of connection lines and a line-free area. The fan-out lines are electrically connected to the pixel array. Each connection line connects one of the driver bonding pads and one of the fan-out lines correspondingly. The auxiliary metal pattern is disposed at the line-free area. The auxiliary metal pattern and the connection lines are arranged in a same interval.

### CROSS-REFERENCE TO RELATED APPLICATION

This application claims the priority benefit of Taiwan application serial no. 99220793, filed on Oct. 27, 2010. The entirety of the above-mentioned patent application is hereby incorporated by reference herein and made a part of this specification.

### BACKGROUND OF THE UTILITY MODEL

1. Field of the Utility Model

The present invention generally relates to a liquid crystal display panel (LCD panel), and more particularly, to an active device array substrate of an LCD panel.

2. Description of Related Art

Along with the progress of the image display technology by leaps and bounds, the displays used for common TV sets or computers have gradually evolved from the early CRT display to the nowadays LCD. The LCD panel applied in an LCD normally comprises an active device array substrate, an opposite substrate and a liquid crystal layer disposed between the above-mentioned two substrates, wherein the two substrates adhere together by using sealant so as to prevent liquid crystal from flowing out.

Generally, an active device array substrate can be partitioned into an active area and a peripheral circuit area. A plurality of pixels are disposed in the active area to form a pixel array, while the peripheral circuit area contains a peripheral circuit through design. Therein each pixel includes a thin film transistor (TFT) and a pixel electrode connected to the TFT. Each pixel is enclosed by two adjacent scan lines and two adjacent data lines and is electrically connected to a pair of a scan line and a data line. The scan lines and the data lines extend from the active area into the peripheral circuit area and are connected to the above-mentioned peripheral circuit, and then the peripheral circuit is connected to an external driver IC.

Since the driver IC has a specific dimension design, hence the peripheral circuit would concentrate towards an area where the driver IC is located from an end connecting the scan lines and the data lines so as to form a fan-out circuit. Therein, the fan-out circuit has a plurality of fan-out lines and a line-free area without disposing fan-out lines. During an etching process in the production course, since the fan-out lines are not located in the line-free area, hence an uneven density distribution of the disposed circuit between the fan-out lines and the line-free area is presented, which makes the etching liquid excessively etch the disposed wires or insufficiently etch the disposed wires. As a result, the resistances of the disposed wire are different and the production yield is consequently reduced. How to overcome the above-mentioned defect and prevent causing the defect has become an important subject to be solved in the current production technology of LCD panels.

### SUMMARY OF THE UTILITY MODEL

Accordingly, the present invention is directed to an active device array substrate, wherein the auxiliary metal pattern is disposed in a line-free area of each fan-out line unit, which can effectively avoid the disadvantage in the etching process of the prior art that an uneven distribution of disposed wires is presented between the fan-out lines and the line-free area to lead an uneven distribution of etching liquid so as to advance the production yield.

The present invention is also directed to an LCD panel having the above-mentioned active device array substrate.

The present invention provides an active device array substrate, which includes a substrate, a pixel array, a peripheral circuit and at least an auxiliary metal pattern. The substrate has an active area and a peripheral circuit area, wherein the peripheral circuit area is connected to the active area. The pixel array is disposed on the active area of the substrate. The peripheral circuit is disposed on the peripheral circuit area of the substrate. The peripheral circuit includes a plurality of driver bonding pads and a plurality of fan-out line units. Each of the fan-out line units has a plurality of fan-out lines, a plurality of connection lines and a line-free area. The fan-out lines are electrically connected to the pixel array, each connection line is respectively connected between one of the driver bonding pads and one of the fan-out lines and the line-free area is located between the connection lines. The auxiliary metal pattern is disposed at the line-free area, wherein the auxiliary metal pattern and the connection lines are arranged in a same interval.

In an embodiment of the present invention, the above-mentioned auxiliary metal pattern is a bar-like pattern.

In an embodiment of the present invention, the above-mentioned auxiliary metal pattern is a zigzag-like pattern.

In an embodiment of the present invention, the above-mentioned zigzag-like pattern is a square-wave pattern, a sine-wave pattern or a sawtooth-wave pattern.

In an embodiment of the present invention, the above-mentioned peripheral circuit further includes at least a dummy bonding pad and the auxiliary metal pattern is connected to the dummy bonding pad.

In an embodiment of the present invention, the width of the above-mentioned auxiliary metal pattern and the line width of the connection lines are substantially the same.

In an embodiment of the present invention, the above-mentioned pixel array includes a plurality of pixels and a plurality of signal lines. The pixels are disposed on the active area, and the signal lines are disposed on the active area and electrically connected to the pixels.

The present invention also provides an active device array substrate, which includes a substrate, a pixel array, a peripheral circuit and at least an auxiliary metal pattern. The substrate has an active area and a peripheral circuit area, wherein the peripheral circuit area is connected to the active area. The pixel array is disposed on the active area of the substrate. The peripheral circuit is disposed on the peripheral circuit area of the substrate. The peripheral circuit includes a plurality of driver bonding pads and a plurality of fan-out line units. Each of the fan-out line units has a plurality of fan-out lines, a plurality of connection lines and a line-free area. The fan-out lines are electrically connected to the pixel array, each connection line is respectively connected between one of the driver bonding pads and one of the fan-out lines and the line-free area is located between the connection lines. The auxiliary metal pattern is disposed at the line-free area, wherein the auxiliary metal pattern and the line-free area are disposed conformally.

In an embodiment of the present invention, the above-mentioned auxiliary metal pattern is a block-like pattern.

In an embodiment of the present invention, the opposite two sides of the above-mentioned block-like pattern and the adjacent connection lines are disposed conformally.

In an embodiment of the present invention, the above-mentioned pixel array includes a plurality of pixels and a plurality of signal lines. The pixels are disposed on the active area, and the signal lines are disposed on the active area and electrically connected to the pixels.

The present invention further provides an LCD panel, which includes an active device array substrate, an opposite substrate and a liquid crystal layer. The active device array substrate includes a substrate, a pixel array, a peripheral circuit and at least an auxiliary metal pattern. The substrate has an active area and a peripheral circuit area, wherein the peripheral circuit area is connected to the active area. The pixel array is disposed on the active area of the substrate. The peripheral circuit is disposed on the peripheral circuit area of the substrate. The peripheral circuit includes a plurality of driver bonding pads and a plurality of fan-out line units. Each of the fan-out line units has a plurality of fan-out lines, a plurality of connection lines and a line-free area. The fan-out lines are electrically connected to the pixel array, each connection line is respectively connected between one of the driver bonding pads and one of the fan-out lines and the line-free area is located between the connection lines. The auxiliary metal pattern is disposed at the line-free area, wherein the auxiliary metal pattern and the connection lines are arranged in a same interval. The liquid crystal layer is located between the active device array substrate and the opposite substrate.

The present invention further provides an LCD panel, which includes an active device array substrate, an opposite substrate and a liquid crystal layer. The active device array substrate includes a substrate, a pixel array, a peripheral circuit and at least an auxiliary metal pattern. The substrate has an active area and a peripheral circuit area, wherein the peripheral circuit area is connected to the active area. The pixel array is disposed on the active area of the substrate. The peripheral circuit is disposed on the peripheral circuit area of the substrate. The peripheral circuit includes a plurality of driver bonding pads and a plurality of fan-out line units. Each of the fan-out line units has a plurality of fan-out lines, a plurality of connection lines and a line-free area. The fan-out lines therein are electrically connected to the pixel array, each connection line is respectively connected between one of the driver bonding pads and one of the fan-out lines and the line-free area is located between the connection lines. The auxiliary metal pattern is disposed at the line-free area, wherein the auxiliary metal pattern and the line-free area are disposed conformally. The liquid crystal layer is located between the active device array substrate and the opposite substrate.

Based on the description above, in the active device array substrate of the present invention, since the auxiliary metal pattern is disposed in the line-free area of the fan-out line unit, hence during performing an etching process, the etching liquid can be more evenly distributed between the connection lines and the auxiliary metal patterns, which effectively reduces the disadvantage in the etching process of the prior art that an uneven distribution of etching liquid is presented due to uneven distribution of disposed wires so as to advance the production yield. In addition, in the present invention, the auxiliary metal pattern is disposed in the line-free area of the fan-out line unit, so that no extra increased space is needed and the invention does not affect the original interval and design of the connection lines and the driver bonding pads.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a diagram of an LCD panel according to an embodiment of the present invention.

FIG. 1B is a partially enlarged diagram of the peripheral circuit area in FIG. 1A.

FIGS. 2-6 are partially enlarged diagrams of the peripheral circuit areas in a plurality of different embodiments of the present invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

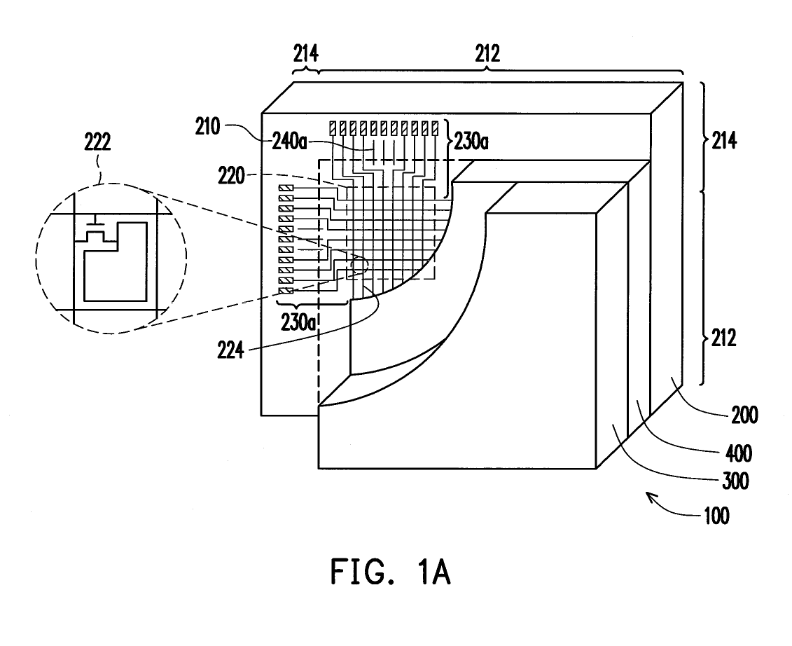

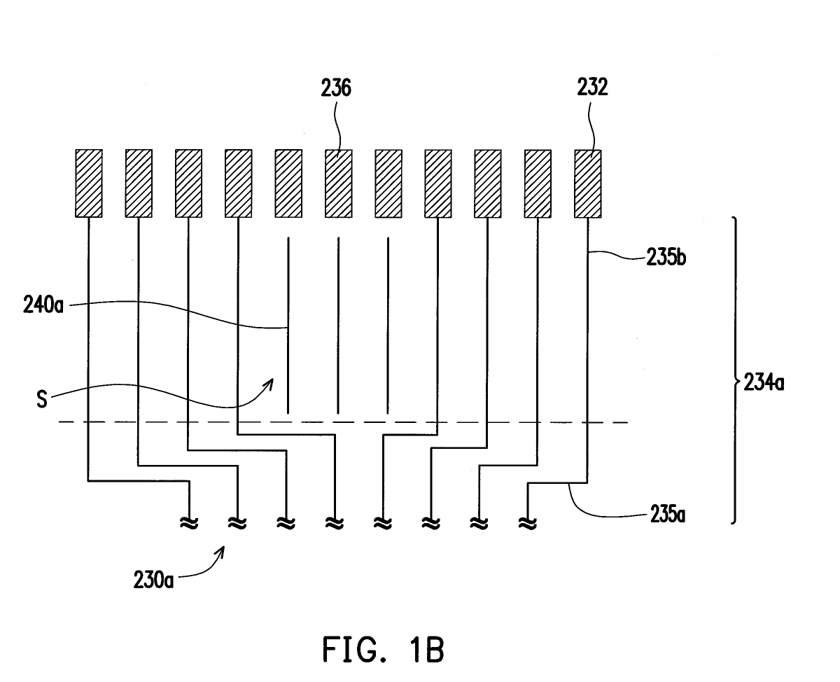

FIG. 1A is a diagram of an LCD panel according to an embodiment of the present invention. FIG. 1B is a partially enlarged diagram of the peripheral circuit area in FIG. 1A. Referring to FIG. 1A at first, in the embodiment, an LCD panel 100 has an active device array substrate 200, an opposite substrate 300 and a liquid crystal layer 400. Therein, the active device array substrate 200 and the opposite substrate 300 are disposed oppositely to each other, and the liquid crystal layer 400 is disposed between the active device array substrate 200 and the opposite substrate 300.

In the embodiment, the active device array substrate 200 is, for example, a TFT array substrate or an active device array substrate of other types, and the opposite substrate 300 is, for example, a color filter substrate. However, the present invention does not limit the types of the active device array substrate 200 and the opposite substrate 300. In other embodiments, the active device array substrate 200 can also be a color filter on array substrate (COA substrate) or an array on color filter substrate (AOC substrate).

Referring to FIGS. 1A and 1B, the active device array substrate 200 includes a substrate 210, a pixel array 220, a peripheral circuit 230a and at least an auxiliary metal pattern 240a (in FIGS. 1A and 1B, a plurality of auxiliary metal patterns are shown). The substrate 210 has an active area 212 and a peripheral circuit area 214, and the peripheral circuit area 214 is connected to the active area 212.

The pixel array 220 is disposed on the active area 212 of the substrate 210. The active area 212 is the area of a display frame. In the embodiment, the pixel array 220 can further include a plurality of pixels 222 on the active area 212 and a plurality of signal lines 224, wherein the signal lines 224 are electrically connected to the pixels 222. In the embodiment, each pixel 222 includes a TFT and a pixel electrode disposed correspondingly to the TFT. The signal lines 224 disposed at the peripheries of the pixels 222 are, for example, scan lines extending horizontally and data lines extending vertically.

The peripheral circuit 230a is disposed on the peripheral circuit area 214 of the substrate 210, and the peripheral circuit 230a is electrically connected to a driving circuit (not shown) and the pixel array 220 in the active area 212. In more details, the peripheral circuit 230a includes a plurality of driver bonding pads 232 and a plurality of fan-out line units 234a, wherein the driver bonding pads 232 are a portion of the peripheral circuit 230a for bonding the driving circuit. Furthermore, each of the fan-out line units 234a has a plurality of fan-out lines 235a, a plurality of connection lines 235b and a line-free area S. The fan-out lines 235a are electrically connected to the pixel array 220, and each connection line 235b is respectively connected between one of the driver bonding pads 232 and one of the fan-out lines 235a.

The auxiliary metal patterns 240a are disposed in the line-free area S of the fan-out line unit 234a, wherein the auxiliary metal patterns 240a are, for example, bar-like patterns and the auxiliary metal patterns 240a and the connection lines 235b are arranged in a same interval. In the embodiment, the width of the auxiliary metal patterns 240a and the line width of the connection lines 235b are substantially the same.

Since the auxiliary metal patterns 240a are disposed in the line-free area S of the fan-out line unit 234a, hence during performing an etching process, the etching liquid can be more evenly distributed between the connection lines 235b and the auxiliary metal patterns 240a, which effectively reduces the disadvantage in the etching process of the prior art that an uneven distribution of etching liquid is presented due to uneven distribution of disposed wires so as to advance the production yield. In addition, in the present invention, the auxiliary metal patterns 240a are disposed in the line-free area S of the fan-out line unit 234a, so that no extra increased space is needed and the invention does not affect the original interval and design of the connection lines 235b and the driver bonding pads 232.

It should be noted that the present invention does not limit the type of the auxiliary metal patterns 240a. Although the auxiliary metal patterns 240a mentioned herein are implemented as bar-like patterns and can be seen as a kind of floating pattern, however other known structure designs with the same function that the etching liquid can be evenly distributed between the connection lines 235b and the line-free area S are also referred as the technical schemes of the present invention, which fall into the scope to be protected of the present invention.

The following embodiments continuously use the part notations and partial content of the above-mentioned embodiment, wherein the same notation represents a same or similar component and meanwhile the same technical description is omitted. The description of the omitted portion can refer to the above-mentioned embodiment and is not duplicated in the following for simplicity.

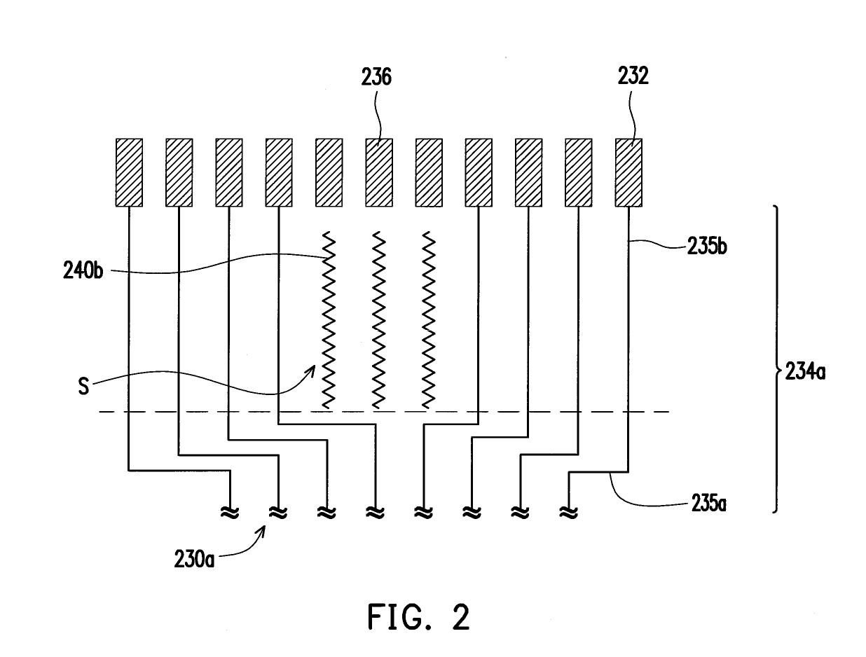

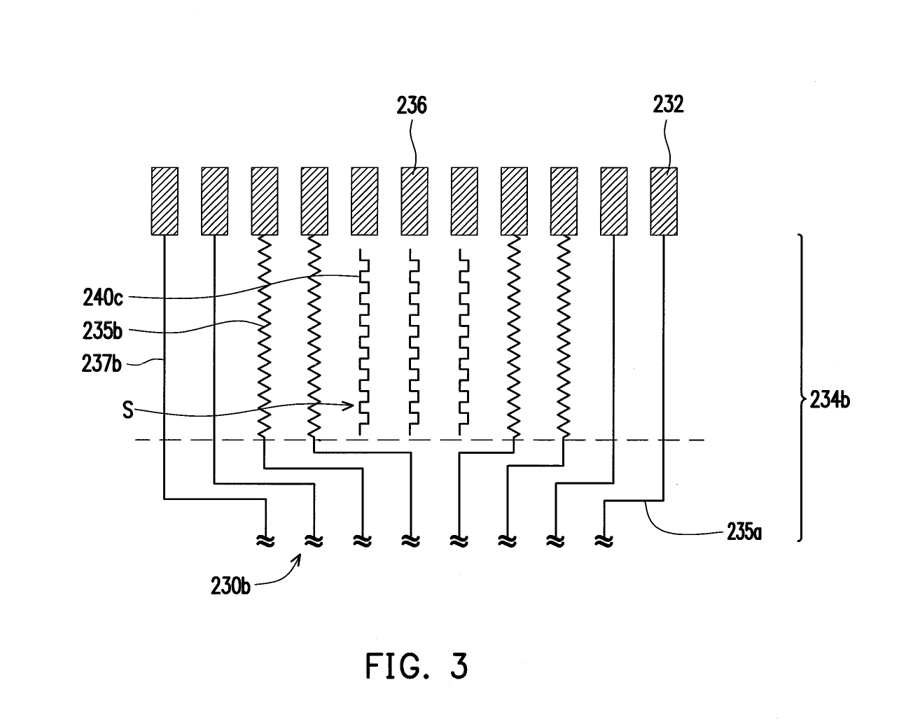

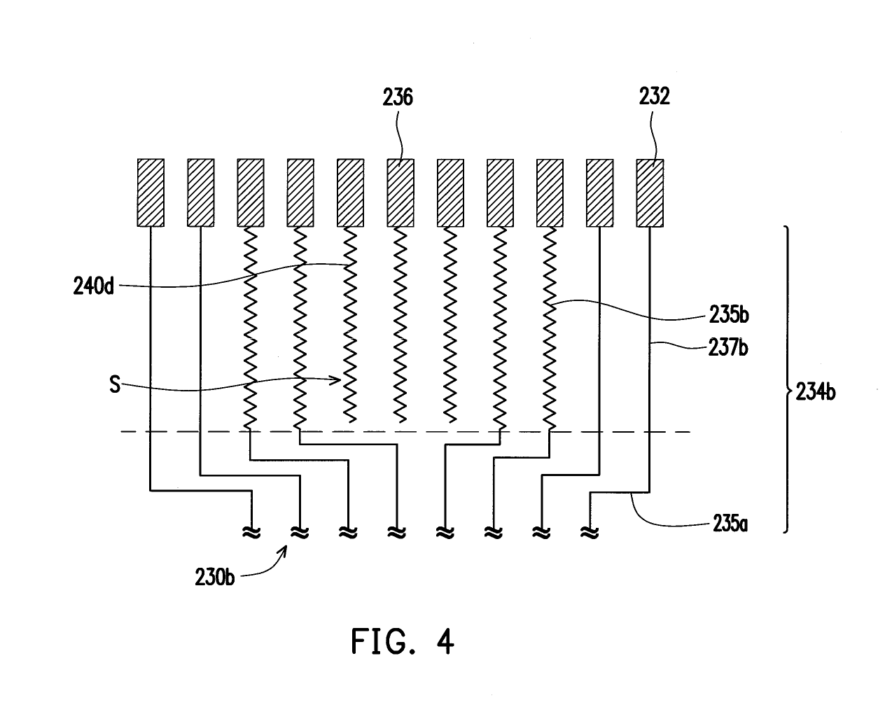

For example, referring to FIG. 2, the auxiliary metal patterns 240b can also indicate a plurality of zigzag-like patterns, wherein the zigzag-like patterns are, for example, a plurality of sawtooth-wave patterns and the sawtooth-wave patterns and the connection lines 235b are arranged in a same interval; or, the auxiliary metal patterns 240c, referring to FIG. 3, can also indicate a plurality of zigzag-like patterns with square-wave pattern shape, wherein in the fan-out line unit 234b of the peripheral circuit 230b, there are two different kinds of connection lines 235b and 237b, for example, the connection lines 235b with sawtooth-wave pattern and the connection lines 237b with bar-like pattern, while the auxiliary metal patterns 240c and the connection lines 235b and 237b are arranged in a same interval; or, in other unshown embodiments, the auxiliary metal patterns can be zigzag-like patterns with sine-wave pattern shape; or, referring to FIG. 4, the peripheral circuit 230b can further include at least a dummy bonding pad 236 and the auxiliary metal patterns 240d (for example, 240d are zigzag-like patterns with sawtooth-wave pattern shape) can be connected to the dummy bonding pad 236.

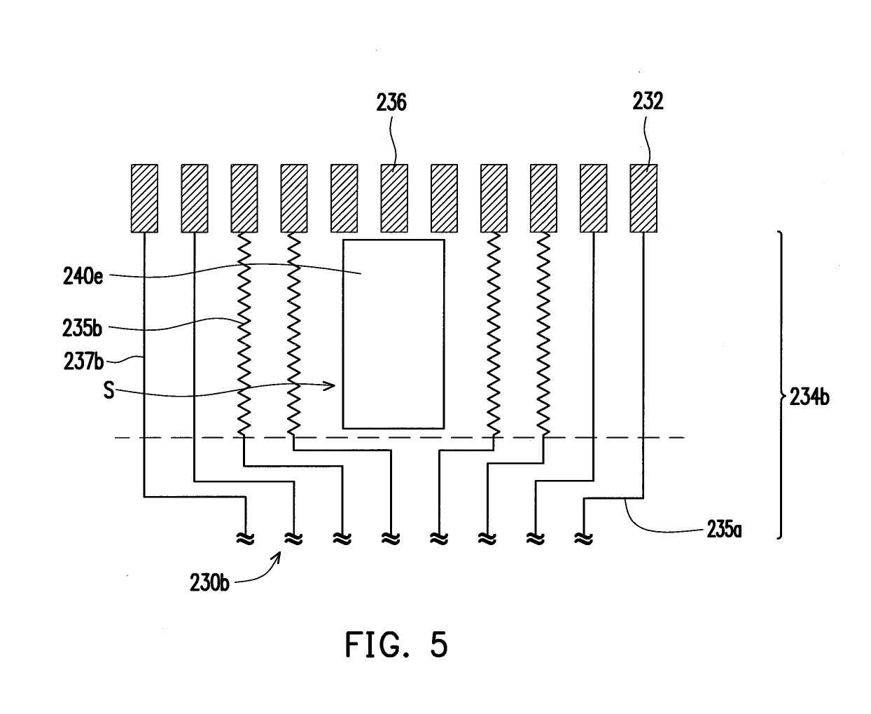

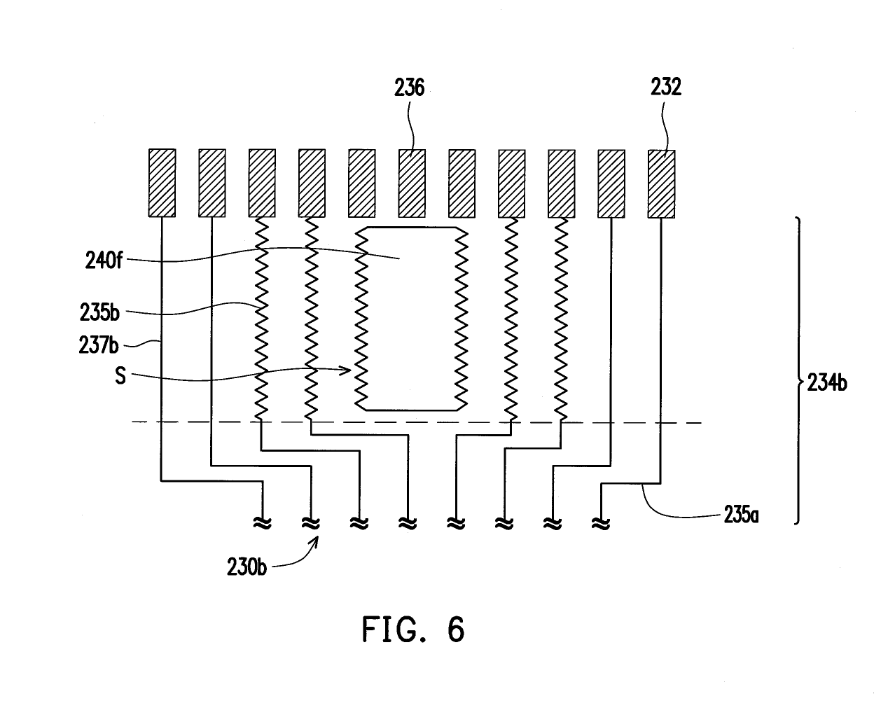

It should be noted that the present invention does not limit the number of the auxiliary metal patterns 240a. Although the auxiliary metal patterns 240a herein are implemented by a plurality of patterns, but in other embodiments, the number of the auxiliary metal pattern can be one. In more details, referring to FIG. 5, the auxiliary metal pattern 240e is, for example, a block-like pattern disposed in the line-free area S of the fan-out line unit 234b, and the auxiliary metal pattern 240e and the line-free area S are substantially disposed conformally; or, referring to FIG. 6, the opposite two sides of the auxiliary metal pattern 240f and the connection lines 235b are substantially disposed conformally. All of the descriptions above are referred as the technical schemes of the present invention, which fall into the scope to be protected of the present invention.

In summary, in the active device array substrate of the present invention, since the auxiliary metal patterns are disposed in the line-free area of the fan-out line unit, hence during performing an etching process, the etching liquid can be more evenly distributed between the connection lines and the auxiliary metal patterns, which effectively reduces the disadvantage in the etching process of the prior art that an uneven distribution of etching liquid is presented due to uneven distribution of disposed wires so as to advance the production yield. In addition, in the present invention, the auxiliary metal patterns are disposed in the line-free area of the fan-out line unit, so that no extra increased space is needed and the invention does not affect the original interval and design of the connection lines and the driver bonding pads.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An active device array substrate, comprising:
a substrate, having an active area and a peripheral circuit area, wherein the peripheral circuit area is connected to the active area;
a pixel array, disposed on the active area of the substrate;
a peripheral circuit, disposed on the peripheral circuit area of the substrate; the peripheral circuit comprising:
a plurality of driver bonding pads; and
a plurality of fan-out line units, wherein each of the fan-out line units has a plurality of fan-out lines, a plurality of connection lines and a line-free area, the fan-out lines are electrically connected to the pixel array, each connection line is respectively connected between one of the driver bonding pads and one of the fan-out lines and the line-free area is located between the connection lines; and
at least an auxiliary metal pattern, disposed at the line-free area, wherein the auxiliary metal pattern and the connection lines are arranged in a same interval.

2. The active device array substrate as claimed in claim 1, wherein the auxiliary metal pattern is a bar-like pattern.

3. The active device array substrate as claimed in claim 1, wherein the auxiliary metal pattern is a zigzag-like pattern.

4. The active device array substrate as claimed in claim 3, wherein the zigzag-like pattern is a square-wave pattern, a sine-wave pattern or a sawtooth-wave pattern.

5. The active device array substrate as claimed in claim 1, wherein the peripheral circuit further comprises at least a dummy bonding pad and the auxiliary metal pattern is connected to the dummy bonding pad.

6. The active device array substrate as claimed in claim 1, wherein the width of the auxiliary metal pattern and the line width of the connection lines are substantially the same.

7. The active device array substrate as claimed in claim 1, wherein the pixel array comprises:
a plurality of pixels, disposed on the active area; and
a plurality of signal lines, disposed on the active area and electrically connected to the pixels.

8. An active device array substrate, comprising:
a substrate, having an active area and a peripheral circuit area, wherein the peripheral circuit area is connected to the active area;
a pixel array, disposed on the active area of the substrate;
a peripheral circuit, disposed on the peripheral circuit area of the substrate; the peripheral circuit comprising:
a plurality of driver bonding pads; and
a plurality of fan-out line units, wherein each of the fan-out line units has a plurality of fan-out lines, a plurality of connection lines and a line-free area, the fan-out lines are electrically connected to the pixel array, each connection line is respectively connected between one of the driver bonding pads and one of the fan-out lines and the line-free area is located between the connection lines; and
at least an auxiliary metal pattern, disposed at the line-free area, wherein the auxiliary metal pattern and the line-free area are disposed conformally.

9. The active device array substrate as claimed in claim 8, wherein the auxiliary metal pattern is a block-like pattern.

10. The active device array substrate as claimed in claim 9, wherein the opposite two sides of the block-like pattern and the adjacent connection lines are disposed conformally.

11. The active device array substrate as claimed in claim 8, wherein the pixel array comprises:
a plurality of pixels, disposed on the active area; and
a plurality of signal lines, disposed on the active area and electrically connected to the pixels.

12. A liquid crystal display panel, comprising:
an active device array substrate, comprising:
a substrate, having an active area and a peripheral circuit area, wherein the peripheral circuit area is connected to the active area;
a pixel array, disposed on the active area of the substrate;
a peripheral circuit, disposed on the peripheral circuit area of the substrate; the peripheral circuit comprising:
a plurality of driver bonding pads; and
a plurality of fan-out line units, wherein each of the fan-out line units has a plurality of fan-out lines, a plurality of connection lines and a line-free area, the fan-out lines are electrically connected to the pixel array, each connection line is respectively connected between one of the driver bonding pads and one of the fan-out lines and the line-free area is located between the connection lines; and
at least an auxiliary metal pattern, disposed at the line-free area, wherein the auxiliary metal pattern and the connection lines are arranged in a same interval;
an opposite substrate; and
a liquid crystal layer, located between the active device array substrate and the opposite substrate.

13. A liquid crystal display panel, comprising:
an active device array substrate, comprising:
a substrate, having an active area and a peripheral circuit area connected to the active area;
a pixel array, disposed on the active area of the substrate;
a peripheral circuit, disposed on the peripheral circuit area of the substrate; the peripheral circuit comprising:
a plurality of driver bonding pads; and
a plurality of fan-out line units, wherein each of the fan-out line units has a plurality of fan-out lines, a plurality of connection lines and a line-free area, the fan-out lines are electrically connected to the pixel array, each connection line is respectively connected between one of the driver bonding pads and one of the fan-out lines and the line-free area is located between the connection lines; and
at least an auxiliary metal pattern, disposed at the line-free area, wherein the auxiliary metal pattern and the line-free area are disposed conformally;
an opposite substrate; and
a liquid crystal layer, located between the active device array substrate and the opposite substrate.
